(19) United States
(12) Patent Application Publication
(10) Pub. No.: US 2006/0263948 A1
(43) Pub. Date: Nov. 23, 2006

(54) Method for manufacturing semicondutor device

(76) Inventor: Hisayuki Maekawa, Miyagi (JP)

Correspondence Address: VOLENTINE FRANCOS, & WHITT PLLC, ONE FREEDOM SQUARE, 11951 FREEDOM DRIVE SUITE 1260, RESTON, VA, 20190, US

(21) Appl. No.: 11/368,419

(22) Filed: Mar. 7, 2006

(30) Foreign Application Priority Data
Mar. 8, 2005 (JP) 063954/2005

(51) Int. Cl. H01L 21/8232; H01L 21/335

(52) U.S. Cl. 438/142

(57) ABSTRACT

A gate oxide film, a gate electrode and low-concentration N type diffusion layers are first formed in a device forming region of a P type silicon substrate. A insulating film is deposited over them and anisotropically etched to form sidewalls. Subsequently, a gate oxide film, a gate electrode and low-concentration N type diffusion layers are formed in a device forming region. An insulating film is deposited over them and anisotropically etched to form sidewalls. The insulating film for the sidewalls and the insulating film for the sidewalls are deposited in discrete processes and the thicknesses of these insulating films are individually adjusted, whereby the widths of the sidewalls can be set to arbitrary values respectively. Thereafter, high-concentration impurity regions are formed on a self-alignment basis by ion implantation.

### BACKGROUND OF THE INVENTION

The present invention relates to a method for manufacturing a semiconductor device, and more specifically to a method for manufacturing a semiconductor device equipped with an LDD (Lightly Doped Drain) structure.

A field effect transistor having, for example, a MOS (Metal Oxide Semiconductor) structure has been known as a basic element of a semiconductor device. There has also been known one having an LDD structure as one type of MOS transistors. The LDD structure is a structure wherein a low-concentration impurity region is provided between a channel forming region and a source-drain region and used to enhance a breakdown voltage characteristic of each MOS transistor. Here, the MOS transistors include one of a low-breakdown voltage (e.g., 10V or lower) and one of a high-breakdown voltage (e.g., 10V or higher), which are slightly different from each other in structure and manufacturing process.

FIG. 5(A) is a sectional view showing a structural example of a low-breakdown voltage N type MOS transistor 510. As shown in FIG. 5(A), a gate oxide film (e.g., silicon oxide film) 512 is formed over a P type silicon substrate 511. A gate electrode (e.g., polysilicon) 513 is formed over the gate oxide film 512. Sidewalls 514 are formed so as to cover side surfaces of the gate electrode 513. On the other hand, low-concentration N type diffusion layers (i.e., offset regions) 515 are formed in the surface of the P type silicon substrate 511 at positions where they are opposite to the sidewalls 514. Further, high-concentration N type impurity regions (source region and drain region) 516 are respectively formed outside these low-concentration N type diffusion layers 515.

FIG. 5(B) is a sectional view showing a structural example of a high-breakdown voltage N type MOS transistor 520. As shown in FIG. 5(B), a gate oxide film 522 is formed over a P type silicon substrate 521. Further, a gate electrode 523 is formed over the gate oxide film 522 and sidewalls 524 that cover side surfaces of the gate electrode 523 are formed. On the other hand, low-concentration N type diffusion layers 525 are formed in the surface of the P type silicon substrate 521 so as to be adjacent to a region (i.e., channel forming region) directly below the gate electrode 523. Further, high-concentration N type impurity regions (i.e., source region and drain region) 526 are formed outside these low-concentration N type diffusion layers 525. Incidentally, the sidewalls 524 may be omitted. When, however, the low-breakdown voltage N type MOS transistor 510 and the high-breakdown voltage N type MOS transistor 520 are formed over the same substrate, the high-breakdown voltage N type MOS transistor 520 may be formed with sidewalls to simplify a manufacturing process (it will be described later).

As understood from the examples shown in FIGS. 5(A) and 5(B), the width L of each offset region is set large in the high-breakdown voltage MOS transistor 520 as compared with the low-breakdown voltage MOS transistor 510. When a breakdown voltage is 10V, for example, the offset width L is set to about 0.5 μm. A high electric field produced at the end of the gate electrode 523 is relaxed by lengthening the offset width L, so that the withstand voltage characteristic of each MOS transistor can be enhanced.

The low-breakdown voltage MOS transistor and the high-breakdown voltage MOS transistor might be formed over the same substrate. A manufacturing process where a low-breakdown voltage N type MOS transistor and a high-breakdown voltage N type MOS transistor are formed over the same P type silicon substrate, will be explained below using FIG. 6.

(1) A device isolation film 602 is first formed over the surface of a P type silicon substrate 601 by using, for example, a LOCOS (local oxidation of silicon) method. Thus, the surface of the P type silicon substrate 601 is divided into a device forming region 603 for forming a high-breakdown voltage N type MOS transistor and a device forming region 604 for forming a low-breakdown voltage N type MOS transistor. A gate oxide film 605 having a thickness of 500 Å, for example, is formed in the surface of the P type silicon substrate 601 by using a normal oxidation technique. Subsequently, the gate oxide film 605 on the device forming region 604 is removed using a normal etching technique or the like. Further, a gate oxide film 606 of 100 Å-thick, for example, is formed in the surface of the device forming region 604 by using the normal oxidation technique (refer to FIG. 6(A)).

(2) Next, a polysilicon film of 3000 Å-thick, for example, is deposited over the entire surface of the P type silicon substrate 601 by using a normal CVD (Chemical Vapor Deposition) technique or the like. Then, the polysilicon film is patterned using a normal photolithography technique or etching technique or the like to thereby form gate electrodes 607 and 608 in the surfaces of the device forming regions 603 and 604 (refer to FIG. 6(B)).

(3) Subsequently, the device forming region 604 is covered with a resist film by using the normal photolithography technique or the like. Phosphorus ions are implanted by a normal ion-implantation technique (e.g., implantation energy of 70 KeV and dose of 5.0×10¹²cm⁻²) with the device isolation film 602 and the gate electrode 607 as masks. Thus, low-concentration N type diffusion layers 609 are formed in the device forming region 603. Further, the resist film is removed and thereafter the device forming region 603 is covered with a resist film. Then, phosphorus ions are implanted by a normal ion-implantation technique (e.g., implantation energy of 30 KeV and dose of 5.0×10¹³cm⁻²) with the device isolation film 602 and the gate electrode 608 as masks. Thus, low-concentration N type diffusion layers 610 are formed in the device forming region 604. Thereafter, the resist film is removed and the formation of the low-concentration N type diffusion layers 609 and 610 is finished (refer to FIG. 6(C)).

(4) Further, an insulating film (e.g., silicon oxide film) of 1000 Å-thick, for example, is deposited over the entire surface of the P type silicon substrate 601 by the normal CVD technique. Thereafter, sidewalls 611 are formed over their corresponding side surfaces of the gate electrode 607 and sidewalls 612 are formed over their corresponding side surfaces of the gate electrode 608 by anisotropic etching. Exposed portions of the gate oxide films 605 and 606 are removed by such anisotropic etching. Consequently, the low-concentration N type diffusion layers 609 of the device forming region 603 and the low-concentration N type diffusion layers 610 of the device forming region 604 are exposed to the surface.

(5) Next, a resist pattern 613 that covers the gate electrode 607, the sidewalls 611 and offset regions (regions in which the low-concentration N type diffusion layers 609 are finally formed) is formed using the normal photolithography technique or the like. When, for example, an N type MOS transistor having a withstand voltage of 10V is formed in the device forming region 603, the low-concentration N type diffusion layers 609 each extending up to a position away 0.5 μm from the end of the gate electrode 607 may be covered with the resist pattern 613.

(6) Arsenic ions are implanted into the P type silicon substrate 601 at, for example, an implantation energy of 40 KeV and a dose of 2.0×10¹⁵cm⁻² by using a normal ion-implantation technique. Thus, the device forming region 603 is ion-implanted with the resist pattern 613 as a mask so that high-concentration impurity regions 614 are formed. High-concentration impurity regions 615 are formed on a self-alignment basis with respect to the device forming region 604 with the gate electrode 608 and the sidewalls 612 as masks (refer to FIG. 6(D)).

Thus, the high-concentration impurity regions 615 of the low-breakdown voltage N type MOS transistor have conventionally been formed on a self-alignment basis with the gate electrode 608 and the sidewalls 612 as the masks, whereas the high-concentration impurity regions 614 of the high-breakdown voltage N type MOS transistor have been formed using the resist pattern 613. Therefore, the conventional manufacturing method was accompanied by drawbacks that the widths (i.e., offset widths) of the low-concentration N type diffusion layers 609 varied due to mask alignment displacements at the formation of the high-concentration impurity regions of the high-breakdown voltage MOS transistor, thus causing variations in breakdown voltage characteristic of the high-breakdown voltage MOS transistor.

It is desirable that the high-concentration impurity regions of the high-breakdown voltage MOS transistor are also formed on a self-alignment basis with the gate electrode and the sidewalls as the masks to suppress the variations in the breakdown voltage characteristic. However, the technique of controlling forming the widths of the sidewalls with a high degree of accuracy is required to use the sidewalls as the masks. This is because each of the widths of the sidewalls must be made coincident with the design value of the width L (refer to FIG. 5(B)) of each offset region to use each sidewall as the mask.

As the technique of controlling the widths of the sidewalls, there is known one described in, for example, the following patent document 1 (Japanese Unexamined Patent Publication No. 2000-100964). According to this technique, the thickness of a gate electrode is changed to adjust the width of each sidewall (refer to the paragraph 0012 of the patent document 1).

There is however a limit to the adjustment of the sidewall width by the thickness of the gate electrode. This is because an adverse effect occurs in that as a gate electrode of an N type MOS transistor is excessively increased in thickness, the gate electrode is brought into depletion, for example (refer to, for example, the paragraph 0011 of the following patent document 2 (Japanese Unexamined Patent Publication No. 2000-58668)).

When gate electrodes are excessively increased in thickness, variations occur in the degree of formation of a sidewall forming material film (silicon oxide film in the above example) at a gap defined between the gate electrodes where the gate electrodes are close to each other, so that the width of each sidewall cannot be controlled with a high degree of accuracy.

Due to such reasons, there has been a demand for a technique for controlling the widths of the sidewalls with high accuracy by adjustments other than by the thicknesses of the gate electrodes in order to form high-concentration impurity regions of a high-breakdown voltage MOS transistor on a self-alignment basis by use of the sidewalls.

### SUMMARY OF THE INVENTION

The present invention has been made in view of the foregoing. It is therefore an object of the present invention to provide a method for manufacturing a semiconductor device, which is capable of controlling the widths of sidewalls with a high degree of accuracy by adjustments other than by the thickness of a gate electrode.

According to a first aspect of the present invention, for attaining the above object, there is provided a method for manufacturing a semiconductor device, comprising a first step for forming a gate insulating film in a surface of a semiconductor substrate, a second step for forming a gate electrode over the gate insulating film, a third step for forming a low-concentration impurity region in the surface of the semiconductor substrate by ion implantation with the gate electrode as a mask, a fourth step for forming a sidewall insulating layer in the surface of the semiconductor substrate, a fifth step for anisotropically etching the sidewall insulating layer to form sidewalls over side surfaces of the gate electrode, and a sixth step for forming a high-concentration impurity region in the surface of the semiconductor substrate by ion implantation with the gate electrode and the sidewalls as masks.

The widths of the sidewalls are controlled by the thickness of the sidewall insulating layer.

According to a second aspect of the present invention, for attaining the above object, there is provided a method for manufacturing a semiconductor device, comprising a first step for forming device isolation regions for dividing a surface of a semiconductor substrate into a first device forming region and a second device forming region, a second step for forming a first gate insulating film over a whole region of the surface of the semiconductor substrate, a third step for forming a first gate electrode over the first gate insulating film of the first device forming region, a fourth step for forming a first low-concentration impurity region in the first device forming region by ion implantation with the first gate electrode as a mask, a fifth step for forming a first sidewall insulating layer of a predetermined thickness in the surface of the semiconductor substrate, a sixth step for anisotropically etching the first sidewall insulating layer to thereby form first sidewalls over side surfaces of the first gate electrode and remove exposed portions of the first gate insulating film, a seventh step for forming a second gate insulating film in the second device forming region, an eighth step for forming a second gate electrode over the second gate insulating film, a ninth step for forming a second low-concentration impurity region in the second device forming region by ion implantation with the second gate electrode as a mask, a tenth step for forming a second sidewall insulating layer having a thickness different from the thickness of the first sidewall insulating layer in the surface of the semiconductor substrate, and an eleventh step for anisotropically etching the second sidewall insulating layer to thereby form second sidewalls different in width from the first sidewalls over side surfaces of the second gate electrode and remove exposed portions of the second gate insulating film.

According to the first aspect of the present invention, the sidewall widths can be controlled with a high degree of accuracy by adjusting the thickness of the sidewall insulating layer.

According to the second aspect of the present invention, the sidewall widths are controlled by the thickness of the sidewall insulating layer, and the sidewall insulating layers different in thickness are respectively formed in the first and second device forming regions in accordance with the individual process steps (fifth and ninth steps). It is therefore possible to form two types of elements whose low-concentration impurity regions are different in width, in one semiconductor substrate.

### BRIEF DESCRIPTION OF THE DRAWINGS

While the specification concludes with claims particularly pointing out and distinctly claiming the subject matter which is regarded as the invention, it is believed that the invention, the objects and features of the invention and further objects, features and advantages thereof will be better understood from the following description taken in connection with the accompanying drawings in which:

FIG. 1 is a process sectional view for describing a method for manufacturing a semiconductor device, according to an embodiment;

FIG. 2 is a process sectional view for describing the method for manufacturing the semiconductor device, according to the above embodiment;

FIG. 3 is a sectional view showing a state of completion of the semiconductor device manufactured by application of the embodiment;

FIG. 4 is a graph showing the relationship between the thicknesses of gate electrodes and insulating films and the widths of sidewalls;

FIG. 5 is a sectional view illustrating a structural example of a conventional N type MOS transistor, in which FIG. 5(A) is a structural example of a low-breakdown voltage N type MOS transistor, and FIG. 5(B) is a structural example of a high-breakdown voltage N type MOS transistor; and

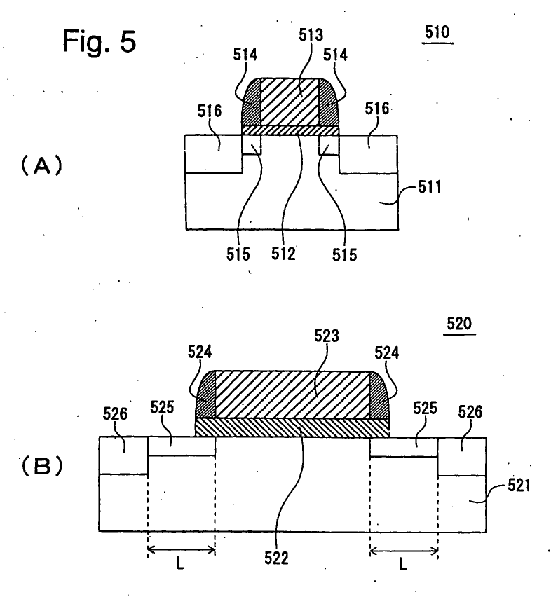

FIG. 6 is a process sectional view for describing a conventional semiconductor device manufacturing method.

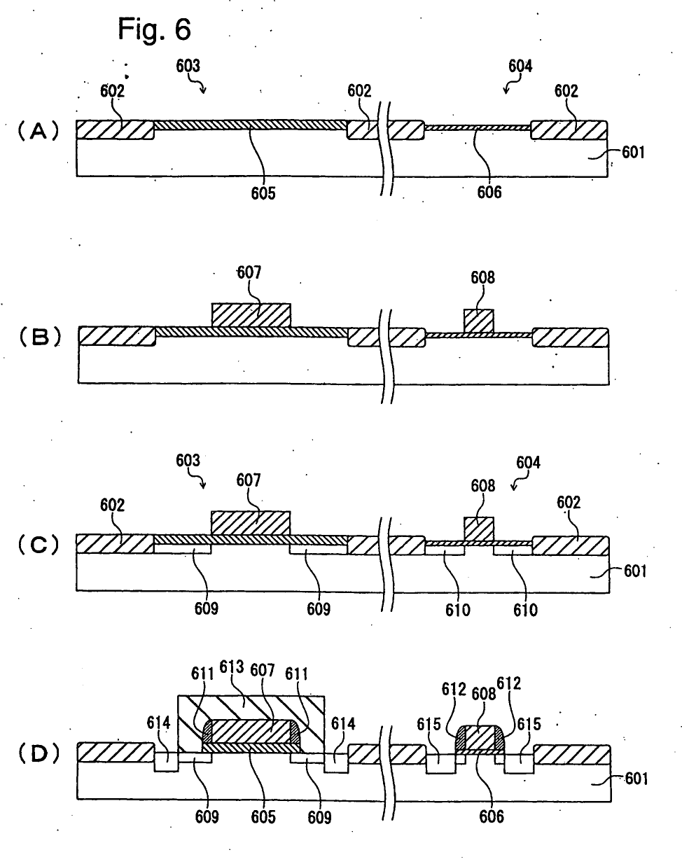

### DETAILED DESCRIPTION OF THE PREFERRED EMBODIMENTS

Preferred embodiments of the present invention will hereinafter be described with reference to the accompanying drawings. Incidentally, the size, shape and physical relationship of each constituent element in the figures are merely approximate illustrations to enable an understanding of the present invention, and further the numerical conditions explained below are nothing more than mere examples.

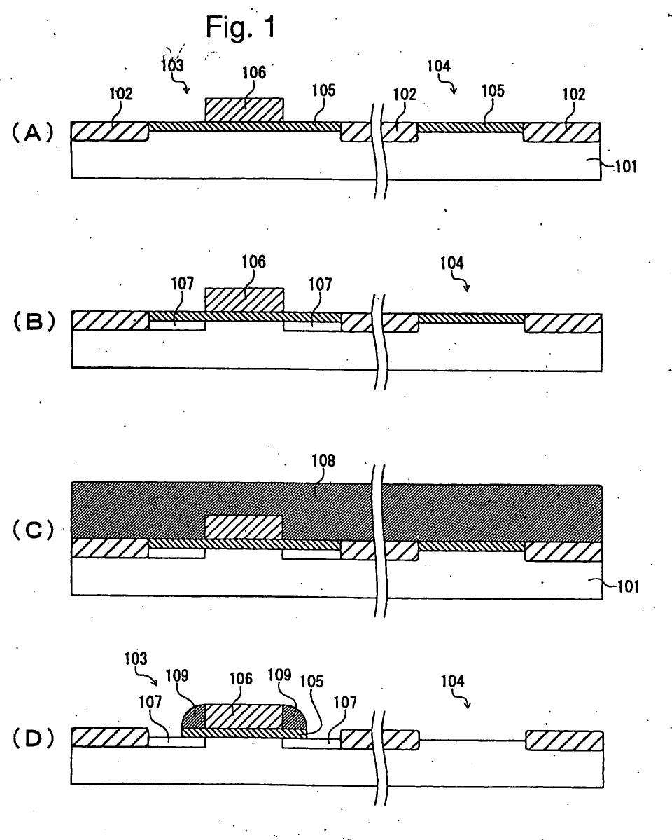

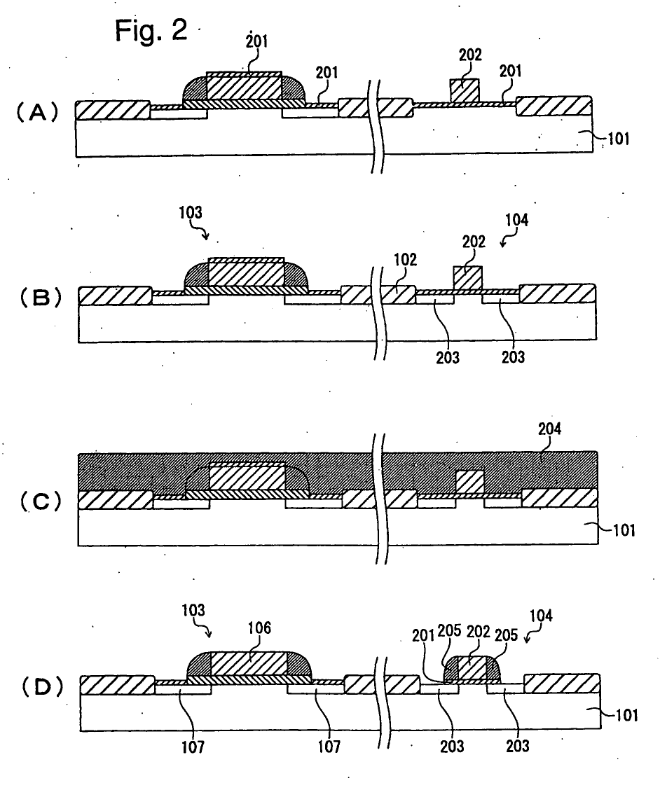

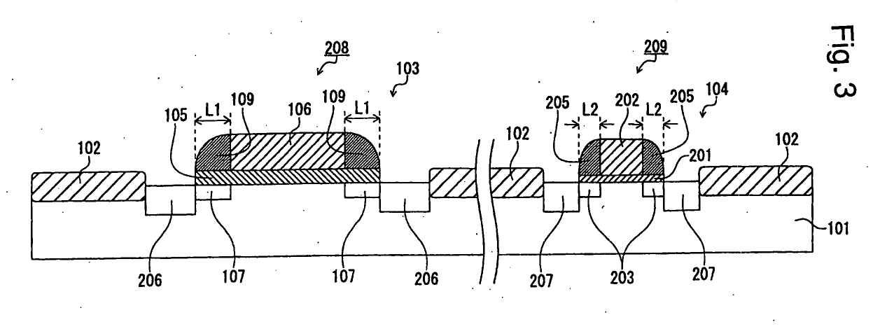

FIGS. 1 and 2 are process sectional views for describing a method for manufacturing a semiconductor device, according to an embodiment. FIG. 3 is a sectional view showing a state of completion of the semiconductor device manufactured by application of the present embodiment.

(1) A device isolation film 102 is formed in the surface of a P-type silicon substrate 101 by using, for example, a LOCOS (local oxidation of silicon) method in a manner similar to the conventional manufacturing process. Thus, the surface of the P type silicon substrate 101 is divided into a device forming region 103 for forming a high-breakdown voltage N type MOS transistor and a device forming region 104 for forming a low-breakdown voltage N type MOS transistor. A gate oxide film 105 having a thickness of 500 Å, for example, is formed in the surface of the P type silicon substrate 101 by using a normal oxidation technique. Subsequently, a polysilicon film of 4000 Å-thick, for example, is deposited over the entire surface of the P type silicon substrate 101 by using a normal CVD (Chemical Vapor Deposition) technique or the like. Further, the polysilicon film is patterned using a normal photolithography technique or etching technique or the like to thereby form a gate electrode 106 in the surface of the device forming region 103 (refer to FIG. 1(A)).

(2) The device forming region 104 is covered with a resist film (not shown) by using the normal photolithography technique or the like. Phosphorus ions are implanted by a normal ion-implantation technique (for example, implantation energy of 70 KeV and dose of 5.0×10¹²cm⁻²) with the device isolation film 102 and the gate electrode 106 as masks. Thus, low-concentration N type diffusion layers 107 are formed in the device forming region 103. Thereafter, the resist film is removed (refer to FIG. 1(B)).

(3) An insulating film 108 is formed over the P type silicon substrate 101 by using the normal CVD technique or the like. Silicon oxide or PSG (phosphosilicate glass) or the like can be used as the material for forming the insulating film 108. A description will now be made, as an example, of a case where a PSG film is formed. The thickness of the PSG film is assumed to be 7000 Å, for example (refer to FIG. 1(C)).

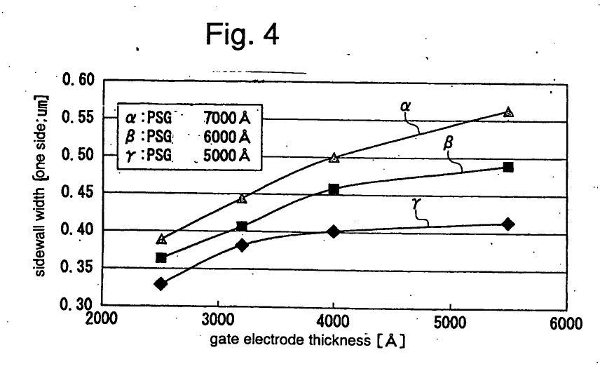

(4) After the formation of the insulating film 108, the insulating film 108 is processed by anisotropic etching to thereby form sidewalls 109 on their corresponding side surfaces of the gate electrode 106 and remove exposed portions of the gate oxide film 105. Thus, the low-concentration N type diffusion layers 107 of the device forming region 103 and the device forming region 104 are exposed (refer to FIG. 1(D)). Since the thickness of the gate electrode 106 is set to 4000 Å and the thickness of the insulating film 108 is set to 7000 Å here, the width of each of the sidewalls 109 and 109 results in about 0.50 μm (refer to FIG. 4 to be described later).

(5) A gate oxide film 201 of 100 Å-thick, for example, is formed over the entire surface of the P type silicon substrate 101. Next, a polysilicon film of the same thickness (4000 Å here) as one in the above process (1) is deposited over the entire surface of the P type silicon substrate 101 by using the normal CVD technique or the like. Further, the polysilicon film is patterned using the normal photolithography technique or etching technique or the like to thereby form a gate electrode 202 in the surface of the device forming region 104 (refer to FIG. 2(A)).

(6) The device forming region 103 is covered with a resist film (not shown) by using the normal photolithography technique or the like. Phosphorus ions are implanted by a normal ion-implantation technique (e.g., implantation energy of 30 KeV and dose of 5.0×10¹³cm⁻²) with the device isolation film 102 and the gate electrode 202 as masks. Thus, low-concentration N type diffusion layers 203 are formed in the device forming region 104. Thereafter, the resist film is removed (refer to FIG. 2(B)).

(7) An insulating film 204 is formed over the P type silicon substrate 101 by using the normal CVD technique or the like. Even though the material for forming the insulating film and its thickness are arbitrary in a manner similar to the process (3), a description will now be made, as an example, of a case where a PSG film of 5000 Å-thick is formed (refer to FIG. 2(C)).

(8) After the formation of the insulating film 204, the insulating film 204 is processed by anisotropic etching to thereby form sidewalls 205 on their corresponding side surfaces of the gate electrode 202 and remove exposed portions of the gate oxide film 201. Thus, the low-concentration N type diffusion layers 203 of the device forming region 104, the low-concentration N type diffusion layers 107 of the device forming region 103 and the surface of the gate electrode 106 are exposed (refer to FIG. 2(D)). Since the thickness of the gate electrode 202 is set to 4000 Å and the thickness of the insulating film 204 is set to 5000 Å here, the width of each of the sidewalls 205 results in about 0.40 μm (refer to FIG. 4 to be described later).

(9) Arsenic ions are implanted into the P type silicon substrate 101 at, for example, an implantation energy of 40 KeV and a dose of 2.0×10¹⁵cm⁻² by using a normal ion-implantation technique. At this time, the device isolation film 102, the gate electrodes 106 and 202, and the sidewalls 109 and 205 are used as masks. Thus, high-concentration impurity regions (i.e., source/drain regions) 206 are formed in the device forming region 103 on a self-alignment basis and at the same time high-concentration impurity regions 207 are formed in the device forming region 104 on a self-alignment basis. Thus, a high-breakdown voltage N type MOS transistor 208 is completed in the device forming region 103, and a low-breakdown voltage N type MOS transistor 209 is completed in the device forming region 104 (refer to FIG. 3).

Regions with no implantation of the arsenic ions, of the low-concentration N type diffusion layers 107 and 203 result in final low-concentration N type diffusion layers (i.e., offset regions). In the present embodiment as described above, the low-concentration N type diffusion layers 107 and 203 are formed with the gate electrodes 106 and 202 as the masks, and further the high-concentration impurity regions 206 and 207 are formed with the gate electrodes 106 and 202 and the sidewalls 109 and 205 as the masks. Accordingly, the widths of the offset regions coincide with the widths L1 and L2 of the sidewalls 109 and 205 respectively. That is, in the present embodiment, the width L1 of each offset region is 0.50 μm and the width L2 of each offset region is 0.40 μm.

Thus, according to the manufacturing method according to the present embodiment, the high-concentration impurity regions 206 can be formed on a self-alignment basis even with respect to the high-breakdown voltage N type MOS transistor 208 as well as the low-breakdown voltage N type MOS transistor 209. It is thus possible to prevent variations in withstand voltage characteristic due to mask alignment displacements at the formation of the high-concentration impurity regions 207.

Besides, according to the manufacturing method according to the present embodiment, the insulating films 108 and 204 different in thickness are formed in the deice forming regions 103 and 104 in accordance with their individual processes (refer to above processes (3) and (7)). Therefore, the two types of N type MOS transistors 208 and 209 of which the low-concentration impurity regions are different in width from each other, can be formed in one P type silicon substrate 101.

In the present embodiment as described above, the widths of the sidewalls 109 and 205 are controlled by adjusting only the thicknesses of the insulating films 108 and 204. However, the widths of the sidewalls 109 and 205 can also be controlled by adjusting both the thicknesses of the insulating films 109 and 205 and the thicknesses of the gate electrodes 106 and 202. FIG. 4 is a graph showing the relationship between the thicknesses of the gate electrodes 106 and 202 and the thicknesses of the insulating films (PSG films in the present embodiment) 108 and 204, and the widths of the sidewalls 109 and 209. In FIG. 4, the horizontal axis indicates the thickness of each of the gate electrodes 106 and 202, and the vertical axis indicates the width of each of the sidewalls 109 and 205. α indicates a case in which the thickness of the PSG film is 7000 Å, β indicates a case in which the thickness of the PSG film is 6000 Å, and γ indicates a case in which the thickness of the PSG film is 5000 Å, respectively.

While the widths of the sidewalls 109 and 205 can be adjusted even depending upon the thickness of the corresponding PSG film alone as is understood from FIG. 4, the widths of the sidewalls 109 and 205 can be controlled with more flexibility and over a wide range by adjusting the thicknesses of both the gate electrodes 106 and 202 and the PSG film.

Incidentally, since there is no need to extremely thicken or thin the thicknesses of the gate electrodes 106 and 202 by combination with the adjustment to the thickness of the PSG film, the above adverse effects such as depletion (refer to the document patent 1) of each gate electrode and the degradation in the accuracy of control on the sidewall width are not incurred.

Although the present embodiment has explained the process of manufacturing the N type MOS transistors by way of example, it is of course needless to say that the present invention can be applied even to the manufacture of P type MOS transistors by N-type/P-type swapping of impurities.

While the preferred form of the present invention has been described, it is to be understood that modifications will be apparent to those skilled in the art without departing from the spirit of the invention. The scope of the invention is to be determined solely by the following claims.

What is claimed is:

1. A method for manufacturing a semiconductor device, comprising:
a first step for forming a gate insulating film in a surface of a semiconductor substrate;
a second step for forming a gate electrode over the gate insulating film;
a third step for forming a low-concentration impurity region in the surface of the semiconductor substrate by ion implantation with the gate electrode as a mask;
a fourth step for forming a sidewall insulating layer in the surface of the semiconductor substrate;
a fifth step for anisotropically etching the sidewall insulating layer to form sidewalls over side surfaces of the gate electrode; and
a sixth step for forming a high-concentration impurity region in the surface of the semiconductor substrate by ion implantation with the gate electrode and the sidewalls as masks,
wherein the widths of the sidewalls are controlled by the thickness of the sidewall insulating layer.

2. The method according to claim 1, wherein the widths of the sidewalls are controlled by the thickness of the sidewall insulating layer and the thickness of the gate electrode.

3. The method according to claim 1, wherein a PSG film is used as the sidewall insulating layer.

4. The method according to claim 2, wherein a PSG film is used as the sidewall insulating layer.

5. A method for manufacturing a semiconductor device, comprising:
a first step for forming device isolation regions for dividing a surface of a semiconductor substrate into a first device forming region and a second device forming region;
a second step for forming a first gate insulating film over a whole region of the surface of the semiconductor substrate;
a third step for forming a first gate electrode over the first gate insulating film of the first device forming region;
a fourth step for forming a first low-concentration impurity region in the first device forming region by ion implantation with the first gate electrode as a mask;
a fifth step for forming a first sidewall insulating layer of a predetermined thickness in the surface of the semiconductor substrate;
a sixth step for anisotropically etching the first sidewall insulating layer to thereby form first sidewalls over side surfaces of the first gate electrode and remove exposed portions of the first gate insulating film;
a seventh step for forming a second gate insulating film in the second device forming region;
an eighth step for forming a second gate electrode over the second gate insulating film;
a ninth step for forming a second low-concentration impurity region in the second device forming region by ion implantation with the second gate electrode as a mask;
a tenth step for forming a second sidewall insulating layer having a thickness different from the thickness of the first sidewall insulating layer in the surface of the semiconductor substrate; and
an eleventh step for anisotropically etching the second sidewall insulating layer to thereby form second sidewalls over side surfaces of the second gate electrode and remove exposed portions of the second gate insulating film.

6. The method according to claim 5 further comprising a twelfth step for simultaneously forming high-concentration impurity regions in the first and second device forming regions by ion implantation with the first gate electrode, the first sidewalls, the second gate electrode and the second sidewalls as masks.

7. The method according to claim 5, wherein the widths of the first and second sidewalls are respectively controlled by both the thicknesses of the first and second sidewall insulating layers and the thicknesses of the first and second gate electrodes.

8. The method according to claim 6, wherein the widths of the first and second sidewalls are respectively controlled by both the thicknesses of the first and second sidewall insulating layers and the thicknesses of the first and second gate electrodes.

9. The method according to any of claim 5, wherein a PSG film is used as the sidewall insulating layers.

10. The method according to any of claim 7, wherein a PSG film is used as the sidewall insulating layers.

11. The method according to any of claim 8, wherein a PSG film is used as the sidewall insulating layers.
